(19) United States
(12) Patent Application Publication
(10) Pub. No.: US 2019/0105598 A1
(43) Pub. Date: Apr. 11, 2019

(54) ELECTRONIC GAS IN-SITU PURIFICATION

(71) Applicant: NUMAT TECHNOLOGIES, INC., SKOKIE, IL (US)

(72) Inventors: Jose ARNO, Portland, OR (US); Mitchell Hugh WESTON, Chicago, IL (US); Glenn M. TOM, Bethany Beach, DE (US); Omar K. FARHA, Morton Grove, IL (US)

(21) Appl. No.: 16/152,474

(22) Filed: Oct. 5, 2018

Related U.S. Application Data
(60) Provisional application No. 62/568,702, filed on Oct. 5, 2017.

(51) Int. Cl. B01D 53/04

(52) U.S. Cl. CPC B01D 53/0446; B01D 53/0423; B01D 53/0438; H01L 21/67017; B01D 2253/204; B01D 2259/401; B01D 2259/45; B01D 2253/202

(57) ABSTRACT

A method of purifying a target fluid containing one or more impurities, the method includes providing the target fluid to a vessel having an adsorbent material located therein, where the absorbent material is a metal organic framework (MOF) or a porous organic polymer (POP), preferentially adsorbing either the target fluid or at least one of the one or more impurities on the adsorbent material, and venting the target fluid from the vessel if the impurities are preferentially adsorbed on the adsorbent material or venting the one or more impurities from the vessel if the target fluid is preferentially adsorbed on the adsorbent material.

### RELATED APPLICATIONS

This application claims the benefit of priority to U.S. Provisional Application No. 62/568,702 filed Oct. 5, 2017, the entire contents of which are hereby incorporated by reference.

### FIELD

The present invention is directed generally to purification of gases and specifically to in-situ purification of gases.

### BACKGROUND

Electronics manufacturing requires the use of a wide range of gases with very high purities (greater than 99.99% pure in most cases). Table 1 below provides a non-limiting summary of gases used in electronics manufacturing. To achieve ultra-high gas purities by conventional methods, highly sophisticated equipment and techniques are required, such as complex cracking, pressure swing adsorption (PSA), vacuum swing adsorption (VSA), thermal swing adsorption (TSA), or cryogenic distillation. Although highly sophisticated, these separation techniques nonetheless often result in low recovery rates which ultimately results in very high production costs. In some cases, the aforementioned separation techniques are inadequate to remove specific impurities. For example, the boiling points of certain gases are so close that they cannot be cryo-separated. In other cases such as filtering with zeolites, the pore size selection of the zeolites are so limited that forecloses design of materials with the size exclusion necessary to achieve the desired separation.

TABLE 1
Electronic Gases

| | | | | |
|---|---|---|---|---|
| Ammonia | Argon | Arsine | Boron trichloride | Boron trifluoride |
| Carbon dioxide | Carbon monoxide | Carbonyl sulfide | Chlorine | Deuterium |
| Diborane | Dichlorosilane | Difluoromethane | Disilane | Ethane |
| Ethylene | Fluorine | Germane | Gallium | Hexafluoroethane |
| Tetrafluoromethane | Perfluoropropane | Trifluoromethane | Difluoromethane | Methyl fluoride |
| Octafluorocyclopentene | Octafluorocyclobutane | Helium | Hydrogen | Xenon |
| Hexafluoroethane | Hydrogen bromide | Hydrogen chloride | Hydrogen fluoride | Hydrogen selenide |
| Hydrogen sulfide | Krypton | Methane | Methyl silane | Methyl fluoride |
| Neon | Nitric oxide | Nitrogen trifluoride | Nitrous oxide | Nitrogen |
| Perfluoropropane | Phosphine | Propylene | Silane | Trisilicon octahydride |
| Silicon tetrachloride | Silicon tetrafluoride | Stibine | Sulfur hexafluoride | Trichlorosilane |
| Trimethylsilane | Tungsten hexafluoride | Acetylene | | |

### SUMMARY

An embodiment is drawn to a method of purifying a target fluid containing one or more impurities, the method includes providing the target fluid to a vessel having an adsorbent material located therein, where the absorbent material is a metal organic framework (MOF) or a porous organic polymer (POP), preferentially adsorbing either the target fluid or at least one of the one or more impurities on the adsorbent material, and venting the target fluid from the vessel if the impurities are preferentially adsorbed on the adsorbent material or venting the one or more impurities from the vessel if the target fluid is preferentially adsorbed on the adsorbent material.

Another embodiment is drawn to a gas purification system comprising a cylinder, an adsorbent material comprising a metal organic framework (MOF) or porous organic polymer (POP) located in the cylinder, wherein the adsorbent material only partially fills the cylinder thereby providing a headspace above the adsorbent material, and the adsorbent material configured to preferentially adsorb target fluid compared to one or more impurities or to preferentially adsorb the one or more impurities compared to the target fluid, and a means for venting the target fluid from the vessel if the impurities are preferentially adsorbed on the adsorbent material or venting the one or more impurities from the vessel if the target fluid is preferentially adsorbed on the adsorbent material. The means may be a valve.

Another embodiment is drawn to method of purifying a target fluid comprising one or more impurities, the method comprising providing the target fluid to a vessel having an adsorbent material located therein, preferentially adsorbing either the target fluid or at least one of the one or more impurities on the adsorbent material, and venting the target fluid from the vessel if the impurities are preferentially adsorbed on the adsorbent material or venting the one or more impurities from the vessel if the target fluid is preferentially adsorbed on the adsorbent material. The vessel is a gas storage cylinder having one valve through which the target fluid is provided into the cylinder and through which the target fluid is delivered from the cylinder.

### BRIEF DESCRIPTION OF THE DRAWINGS

FIG. 1 is a graph comparing the concentration of carbon dioxide in a high pressure arsine source with a MOF adsorbed arsine source.

FIG. 2 is a graph comparing the concentration of water in a high pressure arsine source with a MOF adsorbed arsine source.

FIG. 3 is a graph comparing the concentration of oxygen in a high pressure arsine source with a MOF adsorbed arsine source.

FIG. 4 is a graph comparing the concentration of nitrogen in a high pressure arsine source with a MOF adsorbed arsine source.

FIG. 5 is a graph comparing single-component isotherms of BF₃ and CO₂ adsorbed on MOF CuBTC.

FIG. 6 is a graph illustrating BF₃/CO₂ selectivities as a function of pressure and mol fraction of BF₃.

FIGS. 7A-7C illustrate embodiments of MOF or POP based purification systems including: FIG. 7A a pellet filed tank, FIG. 7B a disk filled tank and FIG. 7A a monolithic filled tank.

FIG. 8 illustrates a point-of-use system according to an embodiment.

### DETAILED DESCRIPTION

Preferably, the ex-situ purification step of producing very high purity gas either through PSA, TSA, VSA, or cryogenic distillation can be circumvented. In such a case, the delivery of adsorbed high purity electronic gases (greater than 99.99% pure) would be accomplished in-situ in a cooperative manner: 1) filling a vessel containing an adsorbent with an electronic gas with a known purity, 2) attaching the vessel filled with the adsorbed electronic gas to a tool (e.g. CVD, etch, ion implant, etc.), and 3) desorbing the electronic gas wherein the electronic gas has a higher purity than the original source filled purity. This preferred scenario delivers high purity electronic gas in-situ and removes the need for rigorous ex-situ purification steps using the aforementioned techniques. The adsorption of low purity gases and liquids into a MOF-filled vessel allows for reversibly adsorbing a desired source material while leaving the impurities un-adsorbed (un-bonded). Alternatively, the impurities are adsorbed, but the source material is not absorbed. Through in-situ processing, the gas delivered from these vessels can have a purity specification higher than the source gas.

In one embodiment, a mixture composed of primarily arsine gas and impurities introduced into a MOF-filled vessel will selectively adsorb arsine gas while the impurities with lower affinity for adsorption will remain in the headspace in a concentrated form. A quick pump down of the headspace will preferentially remove these impurities resulting in a final gas purity that is higher compared to the initial source arsine gas. Other electronic gases from Table I adsorbed and processed this way can be purified in situ by virtue of the adsorption selectivity of MOFs.

Metal-organic frameworks (MOFs) are a class of crystalline, highly porous, tailorable, high performing adsorbent materials which can store and separate gases. MOFs are the coordination product of a metal ion and at least two bidentate organic ligands. Given the highly tailorable nature, MOFs can be tuned for specific pore sizes, pore apertures, pore volumes, surface areas, or chemical affinities. This precise tunability enables the separation of stored gases with very high selectivities for the impurities. Such is the case in the separation and removal of impurities including H₂O, CO₂, N₂, O₂, or SO₂ from electronic gases such as AsH₃, PH₃, BF₃, B₂H₆ or GeF₄.

Embodiments include a storage and delivery vessel, a highly specific adsorbent material, and a process to remove unwanted impurities from the vessel. In an embodiment, an in-situ purification step may be accomplished by adsorbing a semiconductor gas from Table I used in the semiconductor industry with an initial purity of least 95% and containing at least one impurity. In an embodiment, the impurity is preferentially adsorbed to the MOF and the electronic gas is vented from the void space of the vessel. As used herein, the term “preferentially adsorbed” means that one of the target fluid (e.g., electronic gas) or the at least one impurity adsorption to the adsorption material is stronger than the other one of the target fluid or the at least one impurity, or only one of the target fluid (e.g., electronic gas) or the at least one impurity adsorbs (i.e., selectively adsorbs) to the adsorption material and the other ones does not. The impurity is later desorbed from the adsorbent material either through vacuum or heat or both vacuum and heat. In this manner, the electronic gas is selectively separated from the at least one impurity. In an alternative embodiment, impurities are left un-adsorbed and selectively vented (i.e., removed) from the void space of the vessel while the electronic gas is adsorbed to the MOF. Subsequently, the electronic gas is desorbed and delivered from the MOF-filled vessel will have higher purity compared to the original electronic gas stream provided into the vessel. In an embodiment, the vessel comprises a headspace without adsorbent material and a majority, e.g. greater than 50%, such as greater than 90%, of the non-absorbed target fluid, such as a target gas (e.g., electronic gas) or one or more impurities is located in the headspace. During the step of venting, a majority, e.g. greater than 50%, such as greater than 90%, of the non-absorbed target gas or one or more impurities are removed from the vessel during the step of venting, while the majority, e.g. greater than 50%, such as greater than 90%, of the other one of the absorbed target gas or one or more impurities remain in the vessel.

An embodiment includes a typical gas storage device, such as a gas storage cylinder, for example a high pressure cylinder such as those used in conventional compressed gas cylinder storage. The high pressure cylinder may be made of carbon steel or aluminum. The high pressure cylinder may include a threaded valve to deliver and fill the cylinders and a filter to prevent particles from entering or exiting the vessel. The valve or interior of the cylinder may also include additional devices such as integrated pressure regulators, flow restricting devices, flow controllers, flow measuring devices, or pumping systems. The gas storage cylinder, such as a high pressure cylinder may be used for either sub-atmospheric gas storage or high pressure gas storage at a pressure above 1.5 atmospheres.

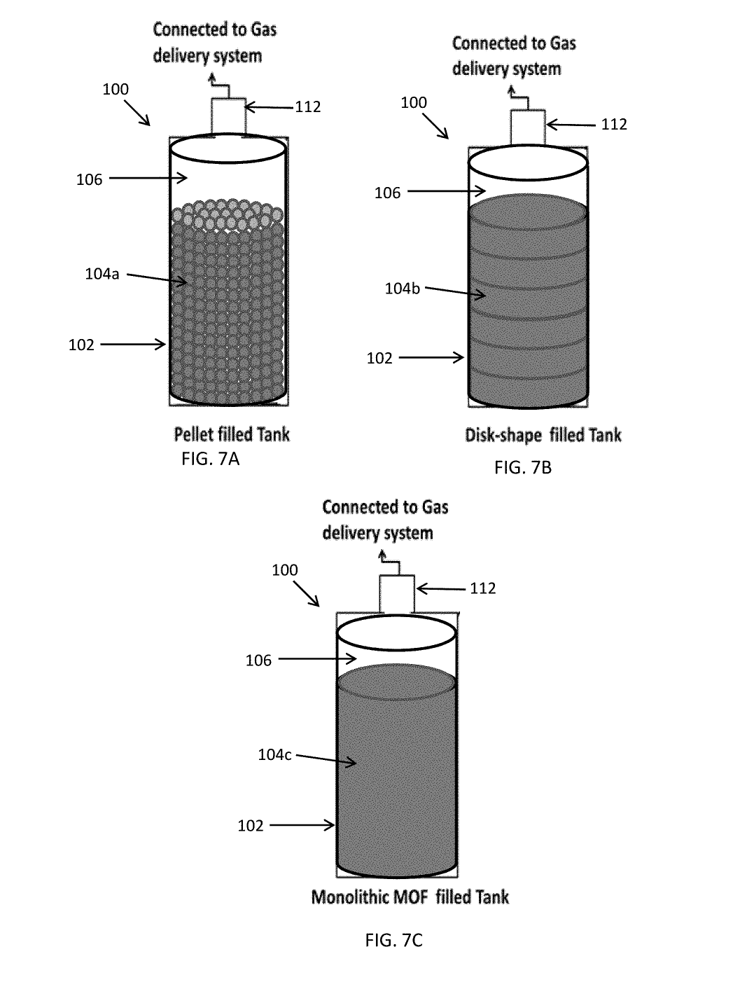

In an embodiment, the chemical adsorbent is a powder, pelletized or monolithic material with an affinity for adsorbing gases of interest which enables the purification of the gases. FIGS. 7A-7C illustrate embodiments of purification systems including FIG. 7(A) a pellet filed tank, FIG. 7(B) a disk filled tank and FIG. 7(C) a monolithic filled tank, discussed in more detail below.

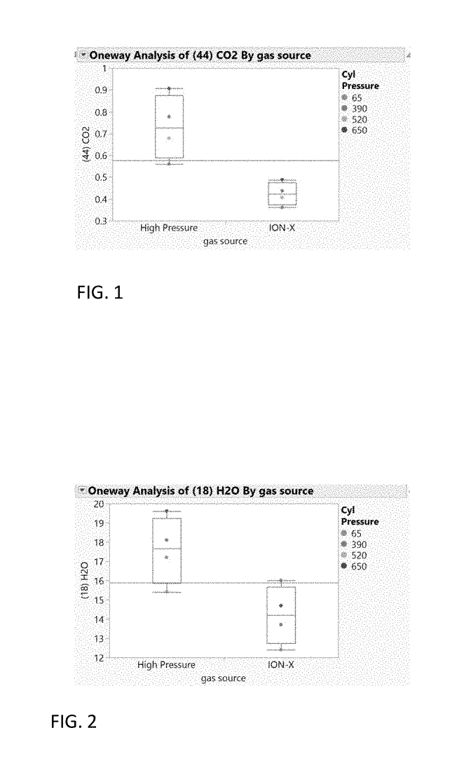

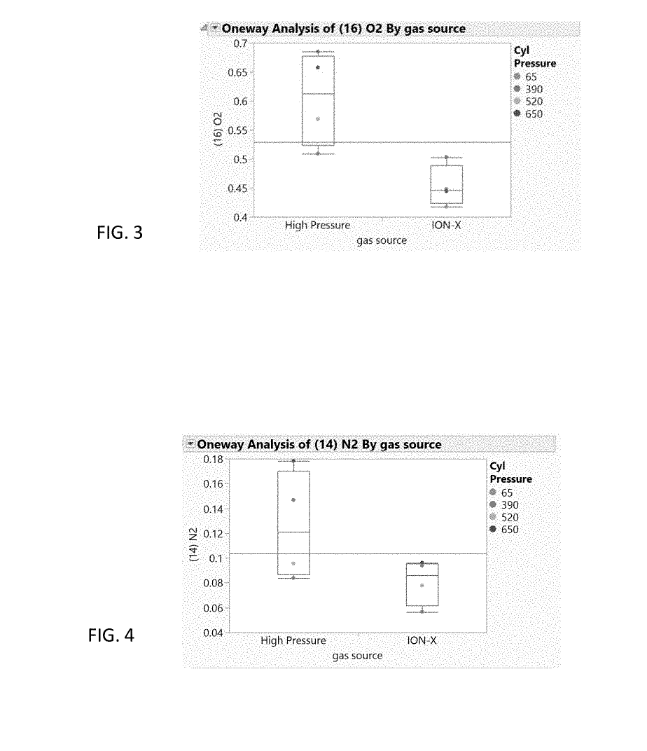

FIGS. 1-4 illustrate the ability to remove impurities from a source gas stream and thereby purify the source gas. The figures depict the gas purity of arsine gas delivered into a gas cylinder filled with a MOF adsorbent and the purity of the same gas after the selective adsorption inside the highly selective porous media. The source gas contained arsine as the main component and nitrogen (N₂), oxygen (O₂), water (H₂O) and carbon dioxide (CO₂) as impurities. FIGS. 1-4 provide a comparative concentration of these impurities at different cylinder pressures. The analyses are performed using mass spectrometry and the values normalized to provide a comparative qualitative measurement.

FIGS. 1-3 show the carbon dioxide, water, and oxygen impurity differences of arsine at varying cylinder pressures between a high pressure source gas used to fill the cylinder (left) and adsorbed gas that is delivered (i.e. desorbed) from an ION-X® MOF adsorbent containing cylinder available from NuMat Technologies Inc. of Skokie, Ill. (right). The results show that there is greater than 95% certainty that the arsine gas delivered from the ION-X® cylinder contains lower levels of these impurities. FIG. 4 shows nitrogen impurity differences at varying cylinder pressures between a high pressure source gas (left) and adsorbed gas that is delivered (i.e. desorbed) from an ION-X® MOF adsorbent containing cylinder (right). The results show that there is greater than 90% certainty that the purity of the gas delivered from the ION-X® cylinder contains less nitrogen impurity.

The adsorbent material is preferably selective to reversibly physi-adsorb a specific molecular or atomic gas. Examples of such materials include: metal organic frameworks (MOFs), porous organic polymers (POP), zeolites, or carbon-based adsorbents, such as activated carbon. In an embodiment, selectivity towards adsorbing a single gas species can be achieved through size exclusion, where the pore size, opening, or shape is such that it allows the source material of interest to be stored in the pore cavity where other materials are shape or size excluded. In other storage exclusion embodiments, selectivity may entail surface attraction (e.g. van der Waals forces) selectively attracting an active component of the gas to the surface of the micropore. In this way, the adsorbent material can be functionalized to preferentially bind to one species while unwanted impurities are left un-adsorbed. In another embodiment, the adsorbent includes a mixture of solid materials, each material designed to trap one or more specific unwanted materials. These molecular traps strongly bind the unwanted impurities so that the gas delivery from that vessel is primarily the preferred material.

In an embodiment of the process, a user loads the adsorbent-filled storage vessel with a gas having a lower grade gas purity than desired. Once inside the cylinder, a desired gas component can be selectively adsorbed to the adsorbent material while impurities stay un-adsorbed, occupying the void space, e.g. headspace in the vessel above the adsorbent material. In a second step, the user then releases the accumulated impurities by venting the gas through the valve. This process can be facilitated by applying vacuum for a short period of time. The venting process can be repeated during or after the fill process to further improve gas purity inside the storage vessel.

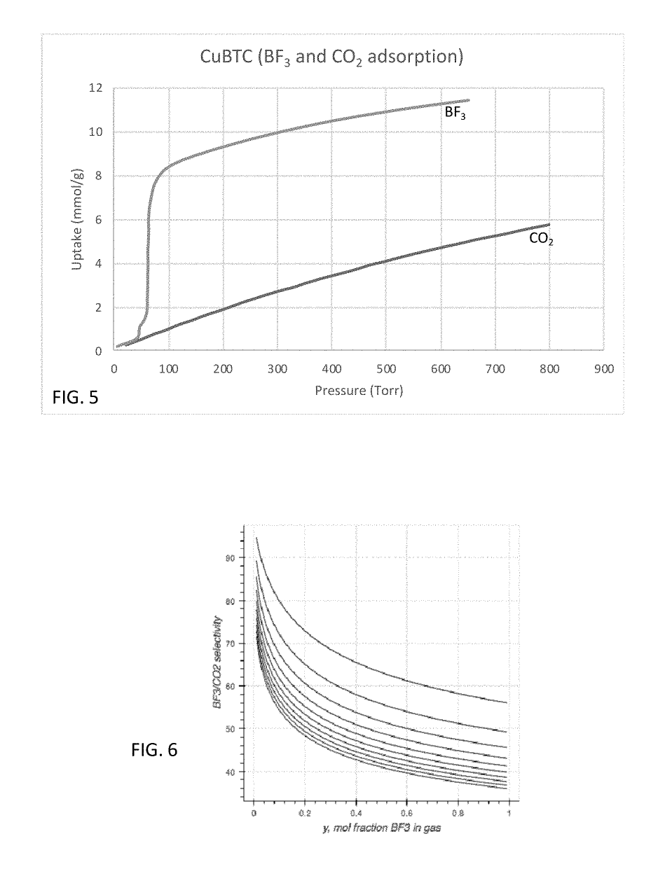

FIGS. 5-6 illustrate the results of experiments separating of BF₃ from CO₂ using Cu-BTC MOF. In these experiments, the BF₃ is more strongly adsorbed (FIG. 5) onto an adsorbent than the CO₂. In these experiments, the selectivity for preferential adsorption of BF₃ ranges from approximately 40-90 depending on the pressure and the molar ratio of BF₃ and CO₂ (FIG. 6). In the case of a 95/5 BF₃/CO₂ gas mixture, none of the CO₂ is adsorbed, allowing for the relative easy removal of the CO₂ from the void space within the cylinder. Once the CO₂ is evacuated, the resulting BF₃ gas has a purity >95%.

Adsorption selectivity inside the vessel can be further enhanced by cooling or heating the vessel during the adsorption and/or venting processes. Similarly, the loading pressure of the cylinder can also be adjusted to achieve higher selectivity between the desired gas and impurities.

In another embodiment, all or selected impurities are selectively chemisorbed or otherwise more tightly bound to the adsorbent material compared to the electronic gas. In this case, the unwanted impurities would remain trapped during the desorption or delivery process resulting in a higher purity desorbed electronic gas compared to the source gas. In a separate process, the impurity-trapping material can be regenerated by applying heat, pressure or other sources of energy for repeat use. In an embodiment, the vessel includes an impurity adsorbent material located therein. In another embodiment, the vessel includes an impurity adsorbent material and an electronic gas adsorbing material located therein, such that the impurity adsorption to the impurity adsorbent material is stronger than adsorption of the electronic gas to the electronic gas adsorbing material.

After performing the above methods, the gas deliverable purity of the desired source gas from the storage vessel will be of greater purity compared to the source gas used to fill it. This passive, in-situ process is more efficient and cost effective compared to conventional cryogenic or swing adsorption purification ex-situ processes. After using the passive purification process, the higher purity gas stored in the adsorbed vessel can be delivered directly to a desired application, e.g., to an ion implantation apparatus for ions to be implanted into a semiconductor device, or compressed into a secondary adsorbent-free container.

In alternative embodiments, the methods described above are used for purification of liquids or low vapor pressure materials. In these embodiments, the adsorbent material can be optimized to achieve the desired adsorption selectivity in the liquid phase.

The above described methods for purifying gases through selective physi-sorption of chemisorption is an improvement over conventional ex-situ gas and liquid purification processes. For example, cryogenic separations are expensive and equipment intensive. Similarly, vacuum, pressure, or heat swing adsorption methods require large systems and energy to achieve high purity grades in industrial gases. Further, the efficiency of these methods can be compromised in cases where the boiling point or other physical/chemical differences between the target gas and impurities are small.

In contrast to conventional methods of purification, the methods described herein exploit desired properties of adsorbents, such as MOFs and POPs. That is, the methods described herein take advantage of the ability to create adsorbent materials having a precise pore size and extremely narrow and uniform pore size distribution.

In the case of adsorbed high purity gases, the adsorbent (such as activated carbon or zeolites) may add minor quantities of undesirable impurities (such as H₂O, CO₂, O₂, or SO₂) which require the need for point-of-use purifiers. Point-of-use purifiers selectively filter out the added impurities. Preferably, the adsorbent would avoid the addition of impurities, thereby discharging a stream of gas with no more impurities than the original high purity source gas. In another embodiment, both the electronic gas and impurity are adsorbed. However, the impurity is more strongly adsorbed to the absorbent. In this method, the desired electronic gas is preferentially desorbed and the undesired impurity remains adsorbed and is not released to the semiconductor tool. In this embodiment, the need to transport highly pure and highly expensive gas is precluded by in-situ purification by the adsorbent on site.

FIGS. 7A-7C illustrate embodiments of MOF or POP based purification systems In the embodiment illustrated in FIG. 7A the purification system 100 includes a vessel 102, such as a high pressure cylinder, an adsorbent material 104a located in the vessel 102 and a headspace 106 located above the adsorbent material 104 in the vessel 102. In this embodiment, the adsorbent material 104 comprises pellets. In the embodiment illustrated in FIG. 7B, the system 100 also includes a vessel 102 with a headspace 106. However, in this embodiment, the adsorbent material 104b comprises a stack of disks. In the embodiment illustrated in FIG. 7C, the system 100 also includes a vessel 102 with a headspace 106. However, in this embodiment, the adsorbent material 104c comprises a single monolith of adsorbent material.

In an embodiment, the vessel 102 includes a single gas inlet/outlet 112 controlled by an inlet valve (not shown for clarity), which may be a single manual valve, a computer controlled valve or a combination thereof. The vessel 102 is provided with an impure gas, e.g., an impure electronic gas, at a pressure above desired storage pressure, e.g. in the range of 650-760 torr, such as 650-665 torr. The inlet valve is closed and the gas is allowed to selectively adsorb to the adsorbent material 104 while the impurity remains in the head space 106. The inlet valve is then opened and gas in the headspace 106 is vented (i.e., removed). In an embodiment, a pressure less than the pressure inside the vessel 102, such as 620-630 torr, is used to draw the non-absorbed gas, e.g. impurities, out of the headspace without desorbing the adsorbed electronic gas. The process can then be repeated. That is, more gas can be provided at 650-665 torr and then the non-absorbed gas located in the headspace is removed from the vessel. If the electronic gas is adsorbed, a purified electronic gas can be stored in the vessel 102 for later use at a desired storage pressure, e.g. 650-660 torr. The purified electronic gas can then be removed from the vessel by pressure swing adsorption (PSA), vacuum swing adsorption (VSA) or thermal swing adsorption (TSA) sufficient to desorb the electronic gas from the adsorbent material. If the impurity gases are adsorbed, the adsorbent material may be regenerated for further use by removing the impurities. The impurities may be removed from the adsorbent material by any suitable method, such as pressure swing adsorption (PSA), vacuum swing adsorption (VSA) or thermal swing adsorption (TSA).

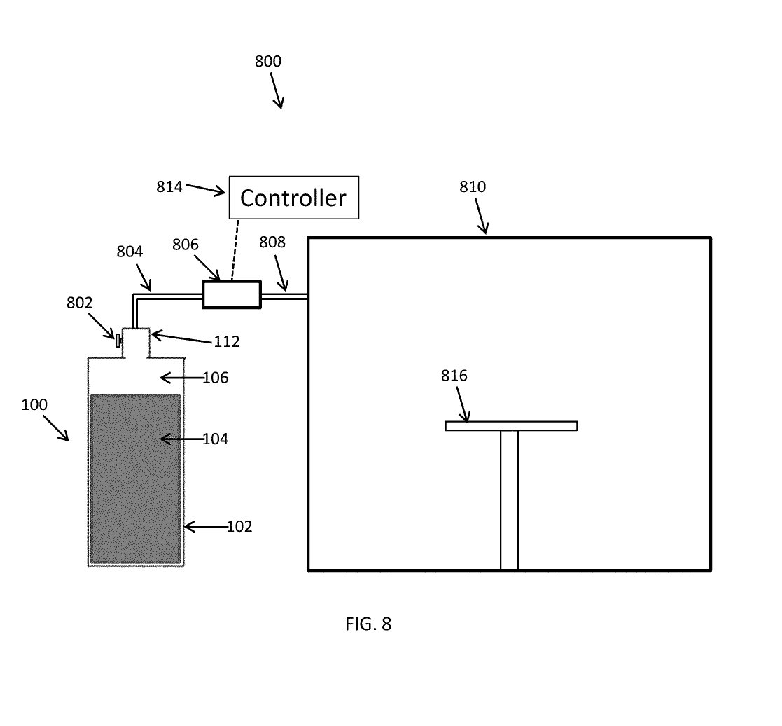

FIG. 8 illustrates a point-of-use system 800 according to an embodiment. In this embodiment, the point-of-use system 800 includes at least one purification system 100, such as a cylinder 102 having a single gas inlet/outlet 112 and an adsorbent material 104 located therein. In an embodiment, the cylinder 102 includes a manual valve 802 at the single gas inlet/outlet 112, which when opened allows the target fluid (e.g., the purified electronic gas) or at least one impurity in the cylinder 102 to exit the cylinder 102 or to be delivered to (i.e., filled into) the cylinder 102. Closing the manual valve 802 prevents the target fluid and/or the impurity from exiting (i.e., being delivered from) the cylinder 102 or entering (i.e., being filled into) the cylinder 102.

The single gas inlet/outlet 112 of the cylinder 102 may be connected to a first end of an electronic actuator 806 either directly or via a first gas flow conduit 804. In an embodiment, the electronic actuator 806 may be attached directly to the single gas inlet/outlet 112 of the cylinder 102, such as by screw threads, and the first gas flow conduit 804 is omitted. Alternatively, a first end of the first gas flow conduit 804 may be attached directly to the single gas inlet/outlet 112 of the cylinder 102, such as by screw threads, and the actuator 806 is attached to the second end of the first gas flow conduit 804.

In an embodiment, the electronic actuator 806 comprises a computer controlled valve, which is connected to a controller 814, such as a computer. The connection may be a wired and/or a wireless connection which allows commands to flow from the controller 814 to the actuator 806. The actuator 806 may be used to regulate the flow of the target fluid and/or at least one impurity in and/or out of the cylinder 102 similarly to the manual valve 802.

A second end of the electronic actuator 806 may be connected to a semiconductor fabrication apparatus 810 either directly or via a second gas flow conduit 808. The semiconductor fabrication apparatus 810 may be, but is not limited to, an etching apparatus, a chemical vapor deposition apparatus, an atomic layer deposition apparatus or an ion implantation apparatus. The semiconductor fabrication apparatus 810 may include a chamber containing a support 816, such as a stage on which a substrate, such as a semiconductor substrate which may contain one or more layers of a semiconductor device (e.g., diode, transistor, capacitor, etc.), is mounted for etching one or more semiconductor device layers or the substrate, for depositing one or more semiconductor device layers, or for implanting ions into one or more semiconductor device layers or the substrate.

Embodiments also include methods of use of the point-of-use system 800. In an embodiment, at least one purification system 100, such as a cylinder 102 having a single gas inlet/outlet 112 and an adsorbent material 104 located therein is filled with an electronic gas having a first impurity concentration at a gas filling facility.

In one embodiment, the impurities are vented from the cylinder 102 at the gas filling facility by pressure, vacuum and/or temperature swing adsorption (i.e., PSA, VSA or TSA) cycle or cycles, while the electronic gas remains preferentially adsorbed to the adsorbent material 104. The cylinder 102 containing the electronic gas adsorbed to the adsorbent material is then shipped to the location of a semiconductor device manufacturing facility having a semiconductor fabrication apparatus 810. The at least one purification system 100 is connected to the semiconductor fabrication apparatus 810 as described above and the purified electronic gas is delivered into the semiconductor fabrication apparatus 810 (e.g., through inlet/outlet 112, one or more gas flow conduits 804/808 and actuator 806) for performing etching, layer deposition, ion implantation or cleaning of the apparatus 810 or substrate. In this manner, the electronic gas undergoes in-situ purification, that is, purification inside the point of use cylinder 102 which is then connected to the semiconductor fabrication apparatus 810. The result of the in-situ purification is that purified electronic gas is provided to the semiconductor fabrication apparatus 810 at a higher purity that the electronic gas initially provided to the at least one purification system 100.

In this embodiment, the target fluid is preferentially (e.g., more strongly or selectively) adsorbed by the adsorbent material 104 and the one or more impurities are removed from the vessel 102 during the venting. The method further comprises removing the target fluid from the vessel 102 after the venting of the impurities. The target fluid may comprise an electronic gas, the adsorbent material 104 may comprises a metal organic framework (MOF) or porous organic polymer (POP) which is configured to preferentially adsorb the electronic gas relative to the one or more impurities, and the step of removing the target fluid from the vessel 102 after the venting comprises providing the electronic gas from the vessel 102 directly into a semiconductor fabrication apparatus 810. As used herein, the term “directly providing” means providing the gas from the vessel 102 into the apparatus 810 through one or more actuators and/or gas flow conduits 804 and/or 808 without storing the gas in an intermediate storage vessel (e.g., another gas storage cylinder). Thus, in one non-limiting embodiment, the vessel 102 may exclude an adsorption bed or column which contains separate gas inlets and outlets and separate inlet and outlet valves, and which requires the purified gas delivered from the bed or column to be stored in an intermediate storage vessel before being provided to a point of use apparatus.

In another embodiment, impurities in the electronic gas provided to the at least one purification system 100 preferentially adsorb on the adsorbent material 104 in the cylinder 102 after filling the cylinder in the gas filling facility. The cylinder 102 containing the electronic gas and the impurities which are preferentially (i.e., stronger) adsorbed to the adsorbent material than the electronic gas is then shipped to the location of a semiconductor device manufacturing facility having a semiconductor fabrication apparatus 810. The at least one purification system 100 is connected to the semiconductor fabrication apparatus 810 as described above and the purified electronic gas is delivered into the semiconductor fabrication apparatus 810, while the impurities remain preferentially adsorbed to the adsorbent material 104 in the cylinder 102. The electronic gas may be provided from the cylinder 102 (e.g., through inlet/outlet 112, one or more gas flow conduits 804/808 and actuator 806) into the apparatus 810 for performing etching, layer deposition, ion implantation or cleaning of the apparatus 810 or substrate. In this manner, the electronic gas undergoes in-situ purification, that is, purification inside the point of use cylinder 102 which is then connected to the semiconductor fabrication apparatus 810. The result of the in-situ purification is that purified electronic gas is provided to the semiconductor fabrication apparatus 810 at a higher purity that the electronic gas initially provided to the at least one purification system 100.

In this embodiment, spent cylinders 102 (i.e., from which the electronic gas is delivered to the apparatus 810) may be returned (i.e., shipped back) to the gas filling facility where adsorbed impurities are removed from the adsorbent material via TSA, PSA or VSA to regenerate the adsorbent material 104. Then, the cylinder 102 may then be re-filled with fresh electronic gas. In this manner, the at least one purification system 100 may be reused.

Thus, in this embodiment, the one or more impurities are preferentially adsorbed to the adsorbent material 104 compared to the target fluid, and the target fluid is removed from the vessel 102 during the venting. The target fluid comprises an electronic gas, the adsorbent material 104 may comprise a metal organic framework (MOF) or porous organic polymer (POP) which is configured to preferentially adsorb the one or more impurities relative to the electronic gas, and the step of venting comprises providing the electronic gas from the vessel 102 directly into a semiconductor fabrication apparatus 810. Optionally, a step of regenerating the adsorbent material 104 may be performed by desorbing the adsorbed one or more impurities after the step of venting, followed by providing additional target fluid (e.g., electronic gas) to the vessel 102.

In summary, the vessel containing the absorbent material 104 may be a storage cylinder 102 having one valve (e.g., valve 802) and one gas inlet/outlet 112 through which the target fluid (e.g., electronic gas) is provided into the cylinder and through which the target fluid is delivered from the cylinder 102. The cylinder 102 comprises a point-of-use cylinder having a headspace 106 without adsorbent material 104 and a majority of the non-absorbed target gas or one or more impurities is located in the headspace.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

What is claimed is:

1. A method of purifying a target fluid comprising one or more impurities, the method comprising:
providing the target fluid to a vessel having an adsorbent material located therein, wherein the absorbent material is a metal organic framework (MOF) or a porous organic polymer (POP);
preferentially adsorbing either the target fluid or at least one of the one or more impurities on the adsorbent material; and
venting the target fluid from the vessel if the impurities are preferentially adsorbed on the adsorbent material or venting the one or more impurities from the vessel if the target fluid is preferentially adsorbed on the adsorbent material.

2. The method of claim 1, wherein the vessel comprises a point-of-use vessel having a headspace without adsorbent material and a majority of the non-absorbed target fluid or one or more impurities is located in the headspace.

3. The method of claim 2, wherein the step of venting comprises removing a majority the non-absorbed target fluid or one or more impurities located in the headspace while a majority of the absorbed target fluid or one or more impurities remain adsorbed.

4. The method of claim 1, wherein the vessel is a high pressure cylinder.

5. The method of claim 1, wherein the vessel is a gas storage cylinder having one valve through which the target fluid is provided into the cylinder and through which the target fluid is delivered from the cylinder.

6. The method of claim 1, wherein the target fluid has purity of at least 95 vol %.

7. The method of claim 1, wherein the absorbent material comprises pores and a pore size, pore opening, or pore shape determines whether the target fluid or the one or more impurities are adsorbed on the adsorbent material.

8. The method of claim 1, further comprising applying a vacuum to improve venting of the fluid or one or more impurities.

9. The method of claim 1, further comprising performing multiple venting steps.

10. The method of claim 1, further comprising at least one of cooling or heating the vessel.

11. The method of claim 1, wherein the target fluid is preferentially adsorbed by the adsorbent material and the one or more impurities are removed from the vessel during the venting, and further comprising removing the target fluid from the vessel after the venting.

12. The method of claim 11, further comprising adjusting a pressure in the vessel to improve the preferential adsorption of the target fluid by the adsorbent material.

13. The method of claim 11, wherein the one or more impurities are removed from the headspace and from a pore volume space of the adsorbent material.

14. The method of claim 11, wherein:
the target fluid comprises an electronic gas;
the adsorbent material comprises the MOF which is configured to preferentially adsorb the electronic gas relative to the one or more impurities; and
the step of removing the target fluid from the vessel after the venting comprises providing the electronic gas from the vessel directly into a semiconductor fabrication apparatus.

15. The method of claim 1, wherein the one or more impurities are preferentially adsorbed to the adsorbent material compared to the target fluid, and the target fluid is removed from the vessel during the venting.

16. The method of claim 15, wherein:
the target fluid comprises an electronic gas;
the adsorbent material comprises the MOF which is configured to preferentially adsorb the one or more impurities relative to the electronic gas; and
the step of venting comprises providing the electronic gas from the vessel directly into a semiconductor fabrication apparatus.

17. The method of claim 16, further comprising regenerating the adsorbent material by desorbing the adsorbed one or more impurities after the step of venting, followed by providing additional target fluid to the vessel.

18. The method of claim 1, wherein the vessel comprises first and second adsorbent materials located therein and the one or more impurities are more strongly adsorbed into the first adsorbent material compared to the target fluid and the target is more strongly adsorbed into the adsorbent material compared to the one or more impurities.

19. A gas purification system comprising:
a cylinder;
an adsorbent material comprising a metal organic framework (MOF) or porous organic polymer (POP) located in the cylinder, wherein the adsorbent material only partially fills the cylinder thereby providing a headspace above the adsorbent material, and the adsorbent material configured to preferentially adsorb target fluid compared to one or more impurities or to preferentially adsorb the one or more impurities compared to the target fluid; and
a means for venting the target fluid from the vessel if the impurities are preferentially adsorbed on the adsorbent material or venting the one or more impurities from the vessel if the target fluid is preferentially adsorbed on the adsorbent material.

20. The system of claim 19, wherein the adsorbent material comprises the MOF which is configured to preferentially adsorb the target fluid comprising an electronic gas compared to the one or more impurities.

21. The system of claim 19, wherein the adsorbent material comprises the MOF which is configured to preferentially adsorb the one or more impurities compared to the target fluid comprising an electronic gas.

22. The system of claim 19, wherein the cylinder is a gas storage cylinder having one valve through which the target fluid is configured to be provided into the cylinder and through which the target fluid is configured to be delivered from the cylinder.

23. The system of claim 19, wherein the vessel comprises first and second adsorbent materials located therein and the one or more impurities are more strongly adsorbed into the first adsorbent material compared to the target fluid and the target fluid is more strongly adsorbed into the adsorbent material compared to the one or more impurities.

24. A method of purifying a target fluid comprising one or more impurities, the method comprising:
providing the target fluid to a vessel having an adsorbent material located therein;
preferentially adsorbing either the target fluid or at least one of the one or more impurities on the adsorbent material; and
venting the target fluid from the vessel if the impurities are preferentially adsorbed on the adsorbent material or venting the one or more impurities from the vessel if the target fluid is preferentially adsorbed on the adsorbent material,
wherein the vessel is a gas storage cylinder having one valve through which the target fluid is provided into the cylinder and through which the target fluid is delivered from the cylinder.

25. The method of claim 24, wherein the cylinder comprises a point-of-use cylinder having a headspace without adsorbent material and a majority of the non-absorbed target fluid or one or more impurities is located in the headspace.

26. The method of claim 24, wherein the target fluid is preferentially adsorbed by the adsorbent material and the one or more impurities are removed from the vessel during the venting, and further comprising removing the target fluid from the vessel after the venting.

27. The method of claim 26, wherein:
the target fluid comprises an electronic gas;
the adsorbent material comprises a metal organic framework (MOF) or porous organic polymer (POP) which is configured to preferentially adsorb the electronic gas relative to the one or more impurities; and
the step of removing the target fluid from the vessel after the venting comprises providing the electronic gas from the vessel directly into a semiconductor fabrication apparatus.

28. The method of claim 24, wherein the one or more impurities are preferentially adsorbed to the adsorbent material compared to the target fluid, and the target fluid is removed from the vessel during the venting.

29. The method of claim 28, wherein:
the target fluid comprises an electronic gas;
the adsorbent material comprises a metal organic framework (MOF) or porous organic polymer (POP) which is configured to preferentially adsorb the one or more impurities relative to the electronic gas; and
the step of venting comprises providing the electronic gas from the vessel directly into a semiconductor fabrication apparatus.

30. The method of claim 28, further comprising regenerating the adsorbent material by desorbing the adsorbed one or more impurities after the step of venting, followed by providing additional target fluid to the vessel.
